(19) United States
(12) Patent Application Publication
(10) Pub. No.: US 2025/0282986 A1
(43) Pub. Date: Sep. 11, 2025

(54) HEAT CONDUCTION SHEET, HEAT DISSIPATING DEVICE, AND METHOD OF MANUFACTURING HEAT CONDUCTION SHEET

(71) Applicant: RESONAC CORPORATION, Minato-ku, Tokyo (JP)

(72) Inventors: Ricardo Mizoguchi GORGOLL, Chiyoda-ku, Tokyo (JP); Nobuyuki TAKAHASHI, Minato-ku, Tokyo (JP); Mika KOBUNE, Chiyoda-ku, Tokyo (JP)

(21) Appl. No.: 18/861,877

(22) PCT Filed: Dec. 23, 2022
(86) PCT No.: PCT/JP2022/047751

§ 371 Date: Oct. 31, 2024

(51) Int. Cl. C09K 5/14; C08J 5/18; C08K 3/04; C08K 5/13; C08K 7/00

(52) U.S. Cl. CPC C09K 5/14; C08J 5/18; C08K 3/042; C08K 5/13; C08K 7/00; C08J 2323/22; C08J 2433/08

(57) ABSTRACT

A heat conduction sheet includes a heat conduction layer containing at least one kind of graphite particle (A) selected from the group consisting of scale-like particles, ellipsoidal particles and rod-like particles, in which in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet, and an adhesive layer containing a resin component and a heat conductive filler, which is located on at least a part of a main surface of the heat conduction layer.

### TECHNICAL FIELD

The present invention relates to a heat conduction sheet, a heat dissipating device, method of manufacturing the heat conduction sheet.

In recent years, the amount of heat generation increases due to high density of mounting density of the wiring and the electronic component in the semiconductor package using a multilayered wiring board, and the amount of heat generation per unit area increases due to the high integration of semiconductor devices. There is a growing demand for increased heat dissipation from semiconductor packages.

In general, a heat dissipating device for dissipating heat by closely adhering a heat conduction grease or a heat conduction sheet between a heat generating body such as a semiconductor package and a heat dissipating body such as aluminum or copper is simply used. In general, heat conduction sheets are superior to heat conduction greases in workability when assembling the heat dissipating device.

In recent years, chips of CPU (central processing unit) tend to be larger in area by multi-core and multi-chip. Further, there is a tendency to lower the pressure of pressure bonding between CPU that is a heat generating body and a heat dissipating body. Therefore, the heat conduction sheet is required to have flexibility at the time of pressure bonding. Further, the heat conduction sheet is required to be excellent in the thermal conductivity so that even if the heat conduction sheet becomes thick due to the chip level difference, the heat conduction sheet has a low thermal resistance.

As the heat conduction sheet, it is also known a resin sheet filled with heat conductive filler. As a resin sheet excellent in the thermal conductivity filled with the heat conductive filler, various resin sheets have been proposed in which inorganic particles with a high thermal conductivity are selected as the heat conductive filler, and further the inorganic particles are oriented perpendicularly to the sheet surface.

For example, the heat conduction sheet (see, for example, Patent Literature 1) in which a heat conductive filler (boron nitride) is oriented in a direction substantially perpendicular to the sheet surface, and the heat conduction sheet (see, for example, Patent Literature 2) having the structure that carbon fibers dispersed in a gel-like substance is oriented perpendicular to the sheet surface has been proposed.

### CITATION LIST

### Patent Literature

Patent Literature 1: Japanese Patent Application Laid-Open (JP-A) No. 2002-26202
Patent Literature 2: Japanese Patent Application Laid-Open (JP-A) No. 2001-250894

### SUMMARY OF INVENTION

### Technical Problem

In Patent Documents 1 and 2, a method of suppressing thermal resistance by orienting a heat conductive filler, a carbon fiber, or the like in a direction perpendicular to the sheet surface is considered. In order to cope with the increase in heat generation due to the high performance and large size of semiconductors, it is desired to further reduce the thermal resistance of heat conduction sheets. Therefore, it is preferable to reduce the thermal resistance by taking into account methods other than the orientation of a heat conductive filler, a carbon fiber, or the like contained in the heat conduction sheet.

It is an object of one embodiment of the present invention to provide a heat conduction sheet with a low thermal resistance, a heat dissipating device provided with this heat conduction sheet and a method of manufacturing a heat conduction sheet capable of manufacturing a heat conduction sheet with a low thermal resistance.

### Solution to Problem

Specific means for addressing the above problem include the following aspects.

<1> A heat conduction sheet, comprising:
a heat conduction layer containing at least one kind of graphite particles (A) selected from the group consisting of scale-like particles, ellipsoidal particles and rod-like particles, wherein in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet, and
an adhesive layer containing a resin component and a heat conductive filler, which is located on at least a part of a main surface of the heat conduction layer.
   <2> The heat conduction sheet according to <1>, wherein the resin component contains at least one selected from the group consisting of a curable resin component, an adhesive resin component, and a thermoplastic resin component.
   <3> The heat conduction sheet according to <2>, wherein the resin component is a curable resin component, and the adhesive layer is semi-cured.
   <4> The heat conduction sheet according to any one of <1> to <3>, wherein the resin component contains a thermoplastic resin component.
   <5> The heat conduction sheet according to any one of <1> to <4>, wherein the thermoplastic resin component contains a thermoplastic epoxy resin.
   <6> The heat conduction sheet according to any one of <1> to <5>, wherein the heat conductive filler contains at least one kind of particles selected from the group consisting of silver, copper, aluminum, aluminum oxide, aluminum hydroxide, magnesium oxide, beryllium oxide, boron nitride, aluminum nitride, silicon nitride, silicon carbide, silicon dioxide, aluminum fluoride, calcium fluoride and zinc oxide.
   <7> The heat conduction sheet according to <6>, wherein the heat conductive filler contains silver particles.
   <8> The heat conduction sheet according to any one of <1> to <7>, wherein a content ratio of the heat conductive filler is from 70% by mass to 99% by mass with respect to a total amount of the adhesive layer.
   <9> The heat conduction sheet according to any one of <1> to <8>, wherein an average thickness of the adhesive layer is from 2 μm to 50 μm.
   <10> A heat dissipating device, comprising a heat generating body, a heat dissipating body, and the heat conduction sheet according to any one of <1> to <9> interposed between the heat generating body and the heat dissipating body,
wherein in the heat conduction layer, the adhesive layer is located on at least a part of a main surface located on the heat generating body side or a main surface located on the heat dissipating body side.
   <11> A heat dissipating device, comprising a heat generating body, a heat dissipating body, and the heat conduction sheet according to any one of <1> to <9> interposed between the heat generating body and the heat dissipating body,
wherein in at least one of an interface between the heat generating body and the heat conduction sheet or an interface between the heat dissipating body and the heat conduction sheet, a void ratio calculated as a ratio of an area of a gas region with respect to an area of a measurement region is from 0% to 25%.
   <11> A method of manufacturing the heat conduction sheet according to any one of <1> to <9>, comprising:
a step of preparing a composition containing the graphite particles (A), a step of forming the heat conduction layer using the composition, and a step of forming an adhesive layer on at least a part of a main surface of the heat conduction layer.

### Advantageous Effects of Invention

In the present disclosure, a heat conduction sheet with a low thermal resistance, a heat dissipating device provided with this heat conduction sheet and a method of manufacturing a heat conduction sheet capable of manufacturing a heat conduction sheet with a low thermal resistance can be provided.

### BRIEF DESCRIPTION OF DRAWINGS

FIG. 1 is a schematic configuration view of a heat conduction sheet, which is an embodiment of the present invention.

FIG. 2 is a schematic cross-sectional view of a heat dissipating device, which is an embodiment of the present invention, when a heat generating body is a semiconductor chip and a heat dissipating body is a heat spreader.

FIG. 3 is a schematic configuration view of a heat conduction sheet incorporated in a heat dissipating device, which is an embodiment of the present invention.

FIG. 4 is a view showing the state of the interface by image analysis in Examples 1 to 2 and Comparative Example 1.

FIG. 5 is a view showing the state of the interface by image analysis in Examples 3 to 7 and Comparative Examples 2 to 4.

### DESCRIPTION OF EMBODIMENTS

Hereinafter, modes for carrying out the present invention will be described in detail. However, the present invention is not limited to the following embodiments. In the following embodiments, the constituent elements (including element steps and the like) are not essential unless otherwise specified. The same applies to numerical values and ranges thereof, and does not limit the present invention.

In the present disclosure, the term “step” includes, in addition to steps independent of other steps, such steps as long as the purpose of the step is achieved even if it cannot be clearly distinguished from other steps.

In the present disclosure, those numerical ranges that are expressed with “to” each denote a range that includes the numerical values stated before and after “to” as the minimum value and the maximum value, respectively.

In a set of numerical ranges that are stated stepwise in the present disclosure, the upper limit value or the lower limit value of a numerical range may be replaced with the upper limit value or the lower limit value of other numerical range. Further, in a numerical range stated in the present disclosure, the upper limit value or the lower limit value of the numerical range may be replaced with a value indicated in Examples.

In the present disclosure, each component may contain plural kinds of substances that correspond to the indicated component. In a case in which there are plural kinds of substances that correspond to the component in a composition, the indicated content ratio or content of the component in the composition means, unless otherwise specified, the total content ratio or content of the plural kinds of substances existing in the composition.

In the present disclosure, each component may contain plural kinds of particles that correspond to the indicated component. In a case in which there are plural kinds of particles that correspond to the component in a composition, the indicated particle size of the component in the composition means, unless otherwise specified, a value determined for a mixture of the plural kinds of particles existing in the composition.

In the present disclosure, the term “layer” or “film” includes, in addition to the case where the region is entirely formed, that when the region where the layer or the film is present is observed, it is formed in only a part of the region.

In the present disclosure, the term “layered” refers to stacking layers, two or more layers may be combined, and two or more layers may be removable.

### [Heat Conduction Layer]

A heat conduction sheet of the present disclosure includes a heat conduction layer containing at least one kind of graphite particles (A) selected from the group consisting of scale-like particles, ellipsoidal particles and rod-like particles, wherein in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet, and an adhesive layer containing a resin component and a heat conductive filler, which is located on at least a part of a main surface of the heat conduction layer.

The heat conduction sheet of the present disclosure includes a heat conduction layer in which the graphite particles (A) is oriented in the thickness direction, and thereby it is considered that thermal conductivity in the thickness direction is excellent and a low thermal resistance is shown.

Furthermore, the heat conduction sheet is considered to exhibit lower thermal resistance by including the aforementioned adhesive layer together with the heat conduction layer containing the graphite particles (A). The reason for this is assumed to be as follows. Note that the present disclosure is not limited to the following speculations. In the heat conduction sheet in which the graphite particles (A) are oriented in the thickness direction, there are unevennesses on a surface that contacts an adherend, and most of the heat resistance is derived from the resistance (also referred to as “contact thermal resistance”) due to a gap generated by contact of the heat conduction sheet and the adherend such as a heat generating body, a heat dissipating body or the like, which is contact with the heat conduction sheet. In the heat conduction sheet of the present disclosure, by disposing the adhesive layer containing a resin component and a heat conductive filler on at least a part of a main surface of the heat conduction layer, the adhesive layer is softened, deformed, or the like by heat, pressure, or the like when the heat conduction sheet and the adherend such as the heat generating body or the heat dissipating body are heat-compression bonded. As the adhesive layer softens, deforms, or the like, a gap (for example, a gap resulting from unevenness of the heat conduction sheet) that is generated when the heat conduction sheet and the adherend are heat-compression bonded, is filled with the adhesive layer. As a result, the heat conduction sheet and the adherend can be brought into close contact via the adhesive layer while reducing a gap between the heat conduction sheet and the adherend, thereby significantly reducing contact thermal resistance.

Contact thermal resistance is also likely to occur when there are unevennesses on a surface of an adherend such as a heat generating body or a heat dissipating body. In this case, it is difficult to reduce the thermal resistance by adjusting the orientation of the heat conductive filler contained in the heat conduction sheet. On the other hand, by using the heat conduction sheet of the present disclosure, the heat conduction sheet and the adherend having unevennesses on a surface can be brought into close contact via the adhesive layer. At this time, the adhesive layer fills a gap generated when the heat conduction sheet and the adherend are heat-compression bonded (for example, a gap resulting from unevenness of the adherend), thereby significantly reducing contact thermal resistance.

The heat conduction layer included in the heat conduction sheet of the present disclosure contains at least graphite particles (A) and may contain a component described below to the extent that the effect of the present disclosure are achieved. Hereinafter, materials used in the heat conduction layer of the present disclosure will be described.

### <Graphite Particles (A)>

The heat conduction layer included in the heat conduction sheet includes graphite particles (A). The graphite particles (A) are considered to function mainly as a high thermal conductivity filler. The graphite particles (A) are at least one kind selected from the group consisting of scale-like particles, ellipsoidal particles and rod-like particles. In a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet. It is preferable that a six-membered ring plane is oriented in a plane direction of the particle in a case of scale-like particles, is oriented in a long axis direction of the particle in a case of ellipsoidal particles, and is oriented in a long axis direction in a case of rod-like particles. A six-membered ring plane is a plane in which a six-membered ring is formed in a hexagonal system, and means a (0001) crystal plane.

It is more preferable that a shape of the graphite particles (A) is scale-like. By selecting a scale-like graphite particles, the thermal conductivity tends to be further improved. This reason can be considered, for example, for the scale-like graphite particles to be more easily oriented in a predetermined direction in the heat conduction layer.

Whether the six-membered ring plane in the crystal is oriented in the plane direction of scale-like particles, the long axis direction of ellipsoidal particles or the long axis direction of rod-like particles, it can be confirmed by X-ray diffraction measurement. The orientation direction of the six-membered ring plane in the crystal of the graphite particle (A) is specifically confirmed by the following method.

At first, a sample sheet for measurement in which the plane direction of scale-like particles, the long axis direction of ellipsoidal particles or the long axis direction of rod-like particles in the graphite particles (A) is oriented along the sheet direction is prepared. As a specific preparation method of the measurement sample sheet, for example, the following method may be mentioned.

A mixture of a resin and the graphite particles (A) in an amount of 10% by volume or more with respect to the resin is sheeted. The “resin” used herein is not particularly limited as long as a material that does not exhibit a peak that interferes with X-ray diffraction and that can form a sheet. Specifically, an amorphous resin having a cohesive force as a binder can be used, such as acrylic rubber, NBR (acrylonitrile butadiene rubber), SIBS (styrene-isobutylene-styrene copolymer), or the like.

The sheet of this mixture is pressed so as to be 1/10 or less of the original thickness, and a plurality of pressed sheets are layered to form a layered body. The operation of further crushing this layered body to the thickness of 1/10 or less is repeated three times or more to obtain a sample sheet for measurement. By this operation, in a case of scale-like particles, a plane direction of the particle is oriented in a plane direction of the sample sheet, in a case of ellipsoidal particles, a long axis direction of the particle is oriented in the plane direction of the sample sheet, and in a case of rod-like particles, a long axis direction of the particle is oriented in the plane direction of the sample sheet.

The X-ray diffraction measurement is performed to the surface of the measurement sample sheet prepared as described above. The height H₁ of the peak corresponding to the (110) plane of graphite appearing around 2θ=77° and the height H₂ of the peak corresponding to the (002) plane of graphite appearing around 2θ=27° are measured. In the measurement sample sheet prepared in this manner, the value obtained by dividing H₁ by H₂ is 0 to 0.02.

From this, it can be seen that “the six-membered ring plane in the crystal of the graphite particle (A) is oriented in the plane direction of scale-like particles, the long axis direction of ellipsoidal particles or the long axis direction of rod-like particles” means that X-ray diffraction measurement is performed on the surface of the sheet including the graphite particle (A), and the value obtained by dividing the peak height corresponding to the (110) plane of the graphite particle (A) appearing around 2θ=77° by the peak height corresponding to the (002) plane of the graphite particle (A) appearing near 2θ=27° is 0 to 0.02.

In the present disclosure, X-ray diffraction measurement is performed under the following conditions.
Device: Bruker AXS KK “D8DISCOVER”
X-ray source: CuKα wavelength 1.5406 nm, 40 kV, 40 mA
Step (measurement step size): 0.01°
Step time: 720 sec

Herein, “in a case of scale-like particles, a plane direction of the particle is oriented in a thickness direction of the heat conduction layer, and in a case of ellipsoidal particles or rod-like particles, a long axis direction of the particle is oriented in the thickness direction of the heat conduction layer” means that the angle (hereinafter also referred to as “orientation angle”) between a plane direction in a case of scale-like particles, a long axis direction in a case of ellipsoidal particles or a long axis direction in a case of rod-like particles, and the surface (main surface) of the heat conduction layer is 60° or more. The orientation angle is preferably 80° or more, more preferably 85° or more, and still more preferably 88° or more.

The orientation angle is an average value when a cross section of the heat conduction layer is observed with SEM (scanning electron microscope), and the angle (orientation angle) between a plane direction in a case of scale-like particles, a long axis direction in a case of ellipsoidal particles or a long axis direction in a case of rod-like particles, and the surface (main surface) of the heat conduction layer for arbitrary 50 graphite particles (A) is measured.

The particle size of the graphite particles (A) is not particularly limited. The average particle size of the graphite particles (A) is preferably a half of the average thickness to the average thickness of the heat conduction layer. When the average particle size of the graphite particles (A) is a half or more of the average thickness of the heat conduction layer, an efficient heat conduction path tends to be formed in the heat conduction layer, and the thermal conductivity tends to be improved. When the average particle size of the graphite particles (A) is equal to or less than the average thickness of the heat conduction layer, the protrusion of the graphite particles (A) from the surface of the heat conduction layer is suppressed, and the adhesion of the surface of the heat conduction layer tends to be excellent.

A method of manufacturing a heat conduction layer so as to be oriented in the plane direction of scale-like particles, the long axis direction of ellipsoidal particles or the long axis direction of rod-like particles, is not particularly limited and for example, the method described in JP-A No. 2008-280496 can be used. Specifically, a method can be used in which sheets are prepared using a composition, the sheets are layered to prepare a layered body, and the side end face of the layered body is sliced (for example, at an angle of 0° to 30° with respect to the normal line extending from the main surface of the layered body) (hereinafter, also referred to as the “layered slice method”).

In the case of using the above-mentioned layered slice method, the particle size of the graphite particles (A) used as the raw material, as a mass average particle size, is preferably a half times or more of the average thickness of the heat conduction layer, and may exceed the average thickness. The reason why the particle size of the graphite particles (A) used as the raw material may exceed the average thickness of the heat conduction layer is, for example, even if the graphite particles (A) having a particle size exceeding the average thickness of the heat conduction layer are included, because the graphite particles (A) are sliced to form the heat conduction layer, the graphite particles (A) do not project from the surface of the heat conduction layer as a result. Further, when the whole graphite particles (A) are sliced in this manner, a large number of graphite particles (A) penetrating in the thickness direction of the heat conduction layer are generated, extremely efficient heat conduction paths are formed, and the heat conductivity tends to be further improved.

When using the layered slice method, the particle size of the graphite particles (A) used as the raw material, as a mass average particle size is more preferably from 1 to 5 times of the average thickness of the heat conduction layer. When the mass average particle size of the graphite particles (A) is 1 or more times the average thickness of the heat conduction layer, a more efficient heat conduction path is formed, and the thermal conductivity is further improved. When the average thickness of the heat conduction layer is 5 times or less, the area of the graphite particles (A) to the surface can be prevented from being too large, and the decrease in the adhesion can be suppressed.

The mass average particle size of the graphite particles (A) (D50) is measured by using a laser diffraction type particle size distribution device adapted to laser diffraction scattering method (e.g., manufactured by Nikkiso Co., Ltd. “Microtrac Series MT3300”), and when the weight cumulative particle size distribution curve is drawn from the small particle size side, it corresponds to the particle size at which the weight cumulative becomes 50%.

The heat conduction layer may contain particles other than scale-like particles, ellipsoidal particles or rod-like particles as graphite particles, and may contain spherical graphite particles, artificial graphite particles, exfoliated graphite particles, acid-treated graphite particles, expanded graphite particles, carbon fiber flakes or the like.

As the graphite particles (A), scale-like particles are preferable, and, from the viewpoint of easily obtaining a scaly having a high degree of crystallinity and a large particle size, scale-like expanded graphite particles obtained by pulverizing sheeted expanded graphite are preferable.

The content ratio of the graphite particles (A) in the heat conduction layer is, for example, from the viewpoint of the balance between the thermal conductivity and the adhesion is preferably from 15% by volume to 50% by volume, more preferably from 20% by volume to 45% by volume, and still more preferably from 25% by volume to 40% by volume.

When the content ratio of the graphite particles (A) is 15% by volume or more, the thermal conductivity tends to be further improved. When the content ratio of the graphite particles (A) is 50% by volume or less, the decrease in the adhesiveness and the adhesion tends to be suppressed.

When the heat conduction layer contains graphite particles other than scale-like particles, ellipsoidal particles or rod-like particles, the content ratio of the entire graphite particles is preferably included in the above range.

The content ratio of the graphite particles (A) (% by volume) is determined by the following Formula.

Content ratio (% by volume) of graphite particles (A)={(Aw/Ad)/((Aw/Ad)+(Xw/Xd))}×100
Aw: mass composition (% by mass) of graphite particles (A)
Xw: mass composition (% by mass) of other optional ingredients
Ad: density of graphite particles (A) (in the present specification, Ad is calculated with 2.1)
Xd: density of other optional ingredients
   <Component (B) that is Liquid at 25° C.>

The heat conduction layer contained in the heat conduction sheet of the present disclosure may contain a component (B) that is liquid at 25° C. (hereinafter, also referred to as “liquid component (B)”). In the present disclosure, “liquid at 25° C.” means a substance that shows fluidity and viscidity at 25° C. and has a viscosity as a measure of viscidity is from 0.0001 Pa·s to 1000 Pa·s at 25° C. In the present disclosure, “viscosity” is defined as a value measured at a shear rate of 5.0 s⁻¹ using a rheometer at 25° C. In particular, the “viscosity” is measured as shear viscosity at a temperature of 25° C. using a rotational shear viscometer equipped with a cone plate (diameter 40 mm, cone angle) 0°.

The viscosity of the liquid component (B) at 25° C. is preferably from 0.001 Pa·s to 100 Pa·s, or more preferably from 0.01 Pa·s to 10 Pa·s.

The liquid component (B) is not particularly limited as long as it is liquid at 25° C., and is preferably a high molecular compound (polymer). Examples of the liquid component (B) include polybutene, polyisoprene, polysulfide, acrylonitrile rubber, silicone rubber, hydrocarbon resin, terpene resin, and acrylic resin. Among these, from the viewpoint of heat resistance, the liquid component (B) preferably contains polybutene. The liquid component (B) may be used alone or in combination of two or more.

Herein, polybutene refers to a polymer obtained by polymerizing isobutene or normal butene. It also includes polymers obtained by copolymerizing isobutene and normal butene. It refers to a polymer having a structural unit represented by “—CH₂—C(CH₃)₂—” or “—CH₂—CH(CH₂CH₃)—” as the structure. It is also sometimes called polyisobutylene. The polybutene only needs to contain the above structure, and other structures are not particularly limited.

Examples of the polybutene include a butene homopolymer and a copolymer of butene and another monomer component. Examples of the copolymer with another monomer component include a copolymer of isobutene and styrene or a copolymer of isobutene and ethylene. The copolymer may be a random copolymer, a block copolymer, or a graft copolymer.

Examples of the polybutene include NOF Corporation's “NOF Polybutene™ Emawet (registered trademark)” JXTG Nippon Oil & Energy Corporation's “Nippon Oil Polybutene” JXTG Nippon Oil & Energy Corporation's “Tetrax” JXTG Nippon Oil & Energy Corporation's “Himol” and Tomoe Engineering Co., Ltd.'s “Polyisobutylene”.

It is thought that the liquid component (B) mainly functions as, for example, a stress reliever and a tackifier, which have excellent heat resistance and humidity resistance. Further, by using it in combination with a hot melt agent (D) described below, there is a tendency that cohesive force, and fluidity during heating can be more improved.

The content ratio of the liquid component (B) in the heat conduction layer is preferably from 10% by volume to 55% by volume, more preferably from 15% by volume to 50% by volume, and still more preferably from 20% volume to 50% by volume from the viewpoint of further increasing adhesive strength, adhesion, sheet strength, hydrolysis resistance, or the like.

When the content ratio of the liquid component (B) is 10% by volume or more, adhesiveness and adhesion tend to be improved. When the content ratio of the liquid component (B) is 55% by volume, there is a tendency that decreases in sheet strength and thermal conductivity can be effectively suppressed.

### <Acrylic Acid Ester Polymer (C)>

The heat conduction layer included in the heat conduction sheet may contain an acrylic ester polymer (C). It is thought that the acrylic ester polymer (C) mainly functions as, for example, a tackifier and an elasticity-imparting agent that allows the thickness to be restored in order to follow warpage.

As the acrylic acid ester-based polymer (C), for example, an acrylic acid ester-based polymer (so-called acrylic rubber) obtained by copolymerizing butyl acrylate, ethyl acrylate, acrylonitrile, acrylic acid, glycidyl methacrylate, 2-ethylhexyl acrylate, or the like as a main raw material component and, if necessary, methyl acrylate, or the like, is preferably used. The acrylic ester polymer (C) may be used alone or in combination of two or more.

The weight average molecular weight of the acrylic ester polymer (C) is preferably from 100,000 to 1,000,000, more preferably from 250,000 to 700,000, and still more preferably from 400,000 to 600,000. When the weight average molecular weight is 100,000 or more, film strength tends to be excellent, and when it is 1,000,000 or less, flexibility tends to be excellent.

The weight average molecular weight can be measured by gel permeation chromatography using a standard polystyrene calibration curve.

The glass transition temperature (Tg) of the acrylic acid ester polymer (C) is preferably 20° C. or lower, more preferably from −70° C. to 0° C., and still more preferably from −50° C. to −20° C. When the glass transition temperature is 20° C. or lower, flexibility and adhesiveness tend to be excellent.

The glass transition temperature (Tg) can be calculated from the tan & derived from dynamic viscoelasticity measurement by tension.

The acrylic ester polymer (C) may be present in the entire heat conduction layer by internal addition, or may be localized on a surface by applying or impregnating it on the surface. In particular, applying it on one side or impregnating it on one side is preferable because strong tackiness can be imparted to only one side, resulting in a sheet with good handling properties.

In the heat conduction layer, the content ratio of the acrylic ester polymer (C) is preferably from 3% by volume to 25% by volume, more preferably from 5% by volume to 20% by volume, and still more preferably from 7% by volume to 15% by volume.

### <Hot Melt Agent (D)>

The heat conduction layer included in the heat conduction sheet may contain a hot melt agent (D). The hot melt agent (D) has the effect of improving the strength of the heat conduction layer and improving the fluidity during heating.

Examples of the hot melt agent (D) include an aromatic petroleum resin, a terpene phenol resin, and a cyclopentadiene petroleum resin. Further, the hot melt agent (D) may be a hydrogenated aromatic petroleum resin or a hydrogenated terpene phenol resin. The hot melt agent (D) may be used alone or in combination of two or more.

Among them, when polybutene is used as the liquid component (B), the hot melt agent (D) preferably contains at least one selected from the group consisting of a hydrogenated aromatic petroleum resin and a hydrogenated terpene phenol resin. These hot melt agents (D) have high stability and excellent compatibility with polybutene, so they tend to be able to achieve better thermal conductivity, flexibility, and handleability when forming a heat conduction layer.

Commercially available hydrogenated aromatic petroleum resins include, for example, “Alcon” by Arakawa Chemical Co., Ltd. and “Imarv” by Idemitsu Kosan Co., Ltd. Furthermore, examples of commercially available hydrogenated terpene phenol resins include “Clearon” manufactured by Yasuhara Chemical Co., Ltd. Commercially available cyclopentadiene petroleum resins include, for example, “Quinton” manufactured by Nippon Zeon Co., Ltd. and “Marcarez” manufactured by Maruzen Petrochemical Co., Ltd.

The hot melt agent (D) is solid at 25° C. and preferably has a softening temperature of from 40° C. to 150° C. When a thermoplastic resin is used as the hot melt agent (D), the softening fluidity during thermocompression bonding is improved, and as a result, adhesion tends to be improved. Further, when the softening temperature is 40° C. or higher, cohesive force can be maintained near room temperature, and as a result, it becomes easier to obtain the necessary sheet strength and tends to be excellent in handleability. When the softening temperature is 150° C. or less, the softening fluidity during thermocompression bonding becomes high, and as a result, adhesion tends to improve. The softening temperature is more preferably from 60° C. to 120° C. Note that the softening temperature is measured by the ring and ball method (JIS K 2207:1996).

The content ratio of the hot melt agent (D) in the heat conduction layer is preferably from 3% by volume to 25% by volume, more preferably from 5% by volume to 20% by volume, and still more preferably from 5% by volume to 15% by volume, from the viewpoint of improving adhesive strength, adhesion, sheet strength, or the like.

When the content ratio of the hot melt agent (D) is 3% by volume or more, adhesive strength, heat fluidity, sheet strength, or the like tend to be sufficient, and when the content ratio is 25% by volume or less, there is a tendency that flexibility is sufficient and handling properties and thermal cycle resistance are excellent.

### <Antioxidant (E)>

The heat conduction layer included in the heat conduction sheet may contain an antioxidant, for example, for the purpose of imparting thermal stability at a high temperature. Examples of the antioxidant (E) include a phenolic type antioxidant, a phosphorus type antioxidant, an amine type antioxidant, a sulfur type antioxidant, a hydrazine type antioxidant, an amide type antioxidant and the like. The antioxidant (E) may be appropriately selected depending on the temperature conditions used, or the like, and a phenolic antioxidant is more preferable. The antioxidant (E) may be used alone or in combination of two or more.

Commercially available phenolic antioxidants include, for example, ADEKA STAB AO-50, ADEKA STAB AO-60, and ADEKA STAB AO-80 manufactured by ADEKA Corporation.

The content ratio of the antioxidant (E) in the heat conduction layer is not particularly limited, and is preferably from 0.1% by volume to 5% by volume, more preferably from 0.2% by volume to 3% by volume, and still more preferably from 0.3% by volume to 1% by volume. When the content ratio of the antioxidant (E) is 0.1% by volume or more, a sufficient antioxidant effect tends to be obtained. When the content ratio of the antioxidant (E) is 5% by volume or less, the strength of the heat conduction layer tends to be prevented from decreasing.

### <Other Ingredients>

The heat conduction layer included in the heat conduction sheet may include other ingredients other than the graphite particles (A), the liquid component (B), the acrylic ester polymer (C), the hot melt agent (D), or the antioxidant (E) depending on the purpose. For example, the heat conduction layer may include a flame retardant for the purpose of imparting flame retardancy. The flame retardant is not particularly limited, and can be appropriately selected from commonly used flame retardants. Examples thereof include a red phosphorus based flame retardant and a phosphoric acid ester based flame retardant can be mentioned. Among them, a phosphoric acid ester based flame retardant is preferable from the viewpoint of excellent safety and improved adhesion due to plasticizing effect.

As the red phosphorus based flame retardants, in addition to pure red phosphorus particles, those provided with various coatings for the purpose of improving safety or stability, or those made into a masterbatch may be used. Specific examples thereof include Nova Red, Nova Excel, Nova Cell, Nova Pellet (all trade names) manufactured by RIN KAGAKU KOGYO Co., Ltd., and the like.

Examples of the phosphoric acid ester based flame retardant include an aliphatic phosphoric acid ester such as trimethyl phosphate, triethyl phosphate, or tributyl phosphate; an aromatic phosphate ester such as triphenyl phosphate, tricresyl phosphate, cresyl diphenyl phosphate, trixylenyl phosphate, cresyl di 2,6-xylenyl phosphate, tris(t-butylated phenyl) phosphate, tris(isopropylated phenyl) phosphate, or triaryl isopropylated phosphate; an aromatic condensed phosphoric acid ester such as resorcinol bisdiphenyl phosphate, bisphenol A bis(diphenyl phosphate), or resorcinol bisdixylenyl phosphate.

Among these, bisphenol A bis (diphenyl phosphate) is preferable from the viewpoint of being excellent in hydrolysis resistance and excellent in the effect of improving the adhesion by a plasticizing effect.

The content ratio of the flame retardant in the heat conduction layer is not limited and may be used in an amount that flame retardancy is exhibited, preferably on the order 30% by volume or less, and from the viewpoint of suppressing the deterioration of the heat resistance due to the flame retardant component exuding to a surface of the heat conduction layer, preferably 20% by volume or less.

The average thickness of the heat conduction layer is not particularly limited, it can be appropriately selected depending on the purpose. The thickness of the heat conduction layer can be appropriately selected depending on the specifications of a semiconductor package to be used, or the like. The smaller the thickness, the lower the thermal resistance tends to be, and the larger the thickness, the higher the warp conformability tends to be. The average thickness of the heat conduction layer may be from 20 μm to 3000 μm, and from the viewpoint of the thermal conductivity and the adhesion, is preferably from 30 μm to 500 μm, and still more preferably from 50 μm to 400 μm.

The average thickness of the heat conduction layer is randomly measured at three locations using an electron microscope to observe a cross section of the object to be measured or using a micrometer, and is given as an arithmetic average value.

### <Adhesive Layer>

The heat conduction sheet of the present disclosure includes an adhesive layer containing a resin component and a heat conductive filler, which is located on at least a part of a main surface of the heat conduction layer.

Examples of the resin component include a curable resin component, an adhesive resin component, a thermoplastic resin component, and the like. Examples of the curable resin component include a thermosetting resin component, a photocurable resin component, and the like. The resin component may include one or more curable resin components, one or more adhesive resin components, or one or more thermoplastic resin components. Further, the resin component may be a mixture of two or more resin components.

Examples of the curable resin component include an epoxy resin, a phenol resin, a melamine resin, a urea resin, an unsaturated polyester resin, an alkyd resin, a urethane resin, a polyimide resins such as a bismaleimide resin, a polyamide resin, a polyamideimide resin, a silicone resin and a thermosetting (meth)acrylic resin. Among these, an epoxy resin is preferred from the viewpoint of adhesion.

Examples of the adhesive resin component, thermoplastic resin component, or the like include polyethylene (PE), polypropylene (PP), polycarbonate (PC), polystyrene, polyvinyl chloride, a vinyl polymer, polyester, polyamide, acrylonitrile-butadiene-styrene copolymer resin (ABS resin), thermoplastic (meth)acrylic resin, acrylonitrile-ethylene-propylene-diene-styrene copolymer resin (AES resin), thermoplastic epoxy resin, phenoxy resin, and thermoplastic elastomer. By using a thermoplastic resin component, the adhesive layer can be easily softened, melted, or the like by heating, and has excellent recyclability and repairability. Furthermore, the heat conduction sheet that uses a thermoplastic resin component has superior storage stability compared to the heat conduction sheet that uses a curable resin component (especially thermosetting resin component), and can be stored at room temperature. Among these, a thermoplastic epoxy resin is preferable as the thermoplastic resin component, since the viscosity can be lowered by heating and a gap between an adherend and the heat conduction sheet can be further reduced.

The thermoplastic resin component may be an amorphous thermoplastic resin, and the amorphous thermoplastic resin may be, for example, at least one of a thermoplastic epoxy resin or a phenoxy resin. The amorphous thermoplastic resin has a melting point (Tm), but in measurement using a differential scanning calorimeter (DSC), it is a resin in which the endothermic peak associated with melting is not confirmed as a clear endothermic peak, or which has a very small endothermic peak.

The heat of fusion of the amorphous thermoplastic resin is preferably 15 J/g or less, more preferably 11 J/g or less, still more preferably 7 J/g or less, and particularly preferably 4 J/g or less, and it is the most preferable that the melting peak is not more than a limit of detection.

The heat of fusion is calculated from the area of the endothermic peak of DSC (differential scanning calorimeter) and the mass of the thermoplastic resin component. At this time, the heat of fusion is calculated using the mass of the thermoplastic resin component excluding components contained in the adhesive layer such as heat conductive filler.

For example, the heat of fusion can be determined as follows.

First, 2 mg to 10 mg of a sample is weighed, placed in an aluminum pan, and heated to 200° C. or higher at 10° C./min using a DSC (for example, DSC8231 manufactured by Rigaku Corporation) to obtain a DSC curve. Next, the heat of fusion is calculated from the area of the endothermic peak during melting determined from the DSC curve and the weighed value.

The thermoplastic epoxy resin is preferably a polymer of (a) difunctional epoxy resin monomer or oligomer and (b) difunctional compound containing two identical or different functional groups selected from the group consisting of a phenolic hydroxyl group, a carboxyl group, a mercapto group, an isocyanate group, and a cyanate ester group. The aforementioned polymer can be produced by heating the (a) component and (b) component in the presence of a catalyst such as an imidazole catalyst.

The above-mentioned (a) difunctional epoxy resin monomer or oligomer refers to an epoxy resin monomer or oligomer having two epoxy groups in the molecule.

Specific examples of the above (a) include a bisphenol A type epoxy resin, a bisphenol F type epoxy resin, a difunctional phenol novolak type epoxy resin, a bisphenol AD type epoxy resin, a biphenyl type epoxy resin, a difunctional naphthalene type epoxy resin, a difunctional alicyclic epoxy resin, a difunctional glycidyl ester type epoxy resin (e.g. diglycidyl phthalate, diglycidyl tetrahydrophthalate and dimer acid diglycidyl ester), a difunctional glycidylamine type epoxy resin (e.g. diglycidyl aniline and dimer glycidyl toluidine), a difunctional heterocyclic epoxy resin, a difunctional diarylsulfone type epoxy resin, a hydroquinone type epoxy resin (e.g. hydroquinone diglycidyl ether, 2,5-di-tert-butylhydroquinone diglycidyl ether, and resorcin diglycidyl ether), a difunctional alkylene glycidyl ether compound (e.g., butanediol diglycidyl ether, butenediol diglycidyl ether, and butynediol diglycidyl ether), a difunctional glycidyl group-containing hydantoin compound (e.g., 1,3-diglycidyl-5,5-dialkylhydantoin and 1-glycidyl-3-(glycidoxyalkyl)-5,5-dialkylhydantoin), a difunctional glycidyl group-containing siloxane (e.g. 1,3-bis(3-glycidoxypropyl)-1,1,3,3-tetramethyldisiloxane and α,β-bis(3-glycidoxypropyl) polydimethylsiloxane) and modified products thereof. Among these, a bisphenol A type epoxy resin, a bisphenol F type epoxy resin and a biphenyl type epoxy resin are preferred from the viewpoint of reactivity and workability.

Examples of the above-mentioned (b) difunctional compound containing a phenolic hydroxyl group include a mononuclear aromatic dihydroxy compound having one benzene ring such as catechol, resorcinol, or hydroquinone, a bisphenol compound such as bis(4-hydroxyphenyl)propane (bisphenol A), bis(4-hydroxyphenyl)methane (bisphenol F), bis(4-hydroxyphenyl)ethane (bisphenol AD), or bis(4-hydroxyphenyl)sulfone (bisphenol S), a compound with a fused ring such as dihydroxynaphthalene, a difunctional phenol compound into which an allyl group has been introduced, such as diallyl resorcinol, diallyl bisphenol A, or triallyl dihydroxybiphenyl, dibutyl bisphenol A and the like.

Examples of the above-mentioned (b) difunctional compound containing a carboxyl group include adipic acid, succinic acid, malonic acid, cyclohexanedicarboxylic acid, phthalic acid, isophthalic acid, terephthalic acid and the like.

Examples of the above-mentioned (b) difunctional compound containing a mercapto group include ethylene glycol bisthioglycolate, ethylene glycol bisthiopropionate, and the like.

Examples of the above-mentioned (b) difunctional compound containing an isocyanate group include diphenylmethane diisocyanate (MDI), isophorone diisocyanate (IPDI), hexamethylene diisocyanate (HMDI), tolylene diisocyanate (TDI), and the like.

Examples of the above-mentioned (b) difunctional compound containing a cyanate ester group include 2,2-bis(4-cyanatophenyl)propane, 1,1-bis(4-cyanatophenyl)ethane, bis(4-cyanatophenyl)methane, and the like.

Among the above-mentioned (b), a bifunctional compound containing a phenolic hydroxyl group is preferable from the viewpoint of obtaining a thermoplastic polymer, and a bifunctional compound containing two phenolic hydroxyl groups and a bisphenol structure or a biphenyl structure is preferable from the viewpoint of heat resistance and adhesiveness, and bisphenol A, bisphenol F or bisphenol S is preferable from the viewpoint of heat resistance and cost.

When the above-mentioned (a) is a bisphenol A type epoxy resin, a bisphenol F type epoxy resin, a bisphenol S type epoxy resin, or a biphenyl type epoxy resin, and the above-mentioned (b) is bisphenol A, bisphenol F or bisphenol S, the polymer obtained by the polymerization of the above-mentioned (a) and (b) preferably has a main skeleton including a paraphenylene structure and an ether bond, a main chain connecting them with an alkylene group, and a structure in which a hydroxyl group generated by polyaddition is disposed in the side chain.

The linear structure consisting of a paraphenylene skeleton can increase the mechanical strength of the polymer after polymerization, and the hydroxyl group disposed in the side chain can improve adhesion. As a result, high adhesive strength can be achieved while maintaining the workability of a thermosetting resin.

The epoxy equivalent (molecular weight/epoxy group number) of the thermoplastic epoxy resin may be 1600 g/eq or more, may be 2000 g/eq or more, may be 5000 g/eq or more, or may be 9000 g/eq or more.

The epoxy equivalent of the epoxy resin is a value measured by a method according to JIS K 7236:2009.

The adhesive layer may contain a phenoxy resin as a thermoplastic resin component.

A phenoxy resin is, for example, a polyhydroxy polyether synthesized from a bisphenol compound and epichlorohydrin, and has thermoplasticity.

For the production of phenoxy resins, there are known methods such as a direct reaction between a dihydric phenol and epichlorohydrin, and an additional polymerization reaction between a diglycidyl ether of a dihydric phenol and a dihydric phenol. In the case of a direct reaction between a dihydric phenol and epichlorohydrin, examples of the dihydric phenol include a phenol compound such as bisphenol A, bisphenol F, bisphenol S, biphenol, biphenylene diol, or fluorenediphenyl; and a aliphatic glycol such as ethylene glycol, propylene glycol, or diethylene glycol. Among these, bisphenol A, bisphenol F, bisphenol S, and the like are preferable from the viewpoint of cost, adhesiveness, viscosity, heat resistance, or the like. These may be used alone or in combination of two or more.

It is preferable that the phenoxy resin has a chemical structure similar to that of an epoxy resin, has a main chain in which its main skeleton is formed by a paraphenylene structure and an ether bond and they are connected, and a structure in which a hydroxyl group is disposed in a side chain.

For the thermoplastic epoxy resin and the phenoxy resin, the weight average molecular weight, which is a polystyrene equivalent value measured by GPC (gel permeation chromatography), is, each independently, preferably from 10,000 to 500,000, more preferably from 18,000 to 300,000, and still more preferably from 20,000 to 200,000. The weight average molecular weight is calculated from the elution peak position detected by GPC, and is the molecular weight value in terms of standard polystyrene. When the weight average molecular weight is within this range, there is a good balance between thermoplasticity and heat resistance. When the weight average molecular weight is 10,000 or more, heat resistance is excellent, and when it is 500,000 or less, the viscosity when melted is low and adhesiveness is high.

Examples of the heat conductive filler include metal-containing particles and non-metal particles that have excellent thermal conductivity, and Examples thereof include a metal, a metal oxide, a metal nitride, a metal hydroxide, a metal carbide, a metal fluoride, and carbon. The heat conductive filler may be, for example, a filler having a thermal conductivity of 10 W/(m·K) or more. The heat conductive filler may be insulating or electrically conductive.

The heat conductive filler may be at least one type of particles selected from the group consisting of silver, copper, aluminum, aluminum oxide, aluminum hydroxide, magnesium oxide, beryllium oxide, boron nitride, aluminum nitride, silicon nitride, silicon carbide, silicon dioxide, aluminum fluoride, calcium fluoride and zinc oxide. Among them, silver particles are preferable from the viewpoint of thermal conductivity.

Since boron nitride is an insulating particle, it is preferably used in applications where insulation is required. However, boron nitride has a scale-like shape and anisotropy in thermal conductivity, and is easily oriented in the plane direction, resulting in a tendency for the thermal conductivity in the thickness direction to be low. Therefore, when boron nitride is used, from the viewpoint of thermal conductivity, it is necessary to form the adhesive layer so that the boron nitride is oriented in the thickness direction, which tends to make the step of forming the adhesive layer complicated.

On the other hand, metal particles such as silver, copper, and aluminum have higher thermal conductivity and smaller anisotropy of thermal conductivity than ceramic fillers such as boron nitride. Therefore, it is not necessary to orient the metal particles in the thickness direction when forming the adhesive layer, and the adhesive layer with excellent thermal conductivity can be easily formed, and the thermal resistance of the heat conduction sheet is suitably reduced. Furthermore, by using silver particles as metal particles, sintering of the particles proceeds at a relatively low temperature. Therefore, a network of silver particles is formed by sintering, which tends to provide higher thermal conductivity than other heat conductive fillers. Furthermore, since sintered silver particles have excellent adhesion with an adherend such as a heat generating body, or a heat dissipating body, thermal resistance tends to be further reduced.

The heat conductive filler preferably contains silver particles. When the heat conductive filler contains silver particles, the content ratio of the silver particles may be from 50% by mass to 100% by mass, may be from 80% by mass to 100% by mass, or may be from 90% by mass to 100% by mass, with respect to 100% by mass of the heat conductive filler.

The particle size of the heat conductive filler may be 0.1 μm to 50 μm, may be from 0.2 μm to 20 μm or may be from 0.5 μm to 10 μm, from the viewpoint of excellent thermal conductivity and further reducing a gap between an adherend and the heat conduction sheet.

The particle size (D50) of the heat conductive filler is measured using a laser diffraction particle size distribution device (for example, “Microtrack series MT3300” manufactured by Nikkiso Co., Ltd.) adapted to a laser diffraction/scattering method, and when a mass cumulative particle size distribution curve is drawn from the small particle size side, D50 corresponds to the particle size at which the mass accumulation is 50%.

In the heat conduction sheet of the present disclosure, the adhesive layer may be located on at least a part of a main surface of the heat conduction layer, and may be located on an entire main surface, or may be located on a part of a main surface (e.g., the part in contact with an adherend such as a heat generating body, or a heat dissipating body).

There may be an adhesive layer located on one main surface, or there may be adhesive layers located on two main surfaces.

The content ratio of the resin component contained in the adhesive layer is, for example, from the viewpoint of the balance between the heat conductivity and adhesion, preferably from 1% by mass to 30% by mass, more preferably from 3% by mass to 25% by mass, and still more preferably from 5% by mass to 20% by mass, with respect to the total amount of the adhesive layer.

In a case in which the adhesive layer contains a thermoplastic resin component, the content ratio of the thermoplastic resin component may be 50% by mass or more, may be 60% by mass or more, may be 80% by mass or more, or may be 90% by mass or more, with respect to the total amount of the resin component.

The upper limit of the content ratio of the aforementioned thermoplastic resin component is not particularly limited, may be 100% by mass, or may be 95% by mass or less.

The content ratio of the heat conductive filler contained in the adhesive layer is, for example, from the viewpoint of the balance between the heat conductivity and adhesion, preferably from 70% by mass to 99% by mass, more preferably from 75% by mass to 97% by mass, and still more preferably from 80% by mass to 95% by mass, with respect to the total amount of the adhesive layer.

The total content ratio of the resin component and the heat conductive filler contained in the adhesive layer may be from 80% by mass to 100% by mass, or may be from 90% by mass to 100% by mass, with respect to the total amount of the adhesive layer.

The adhesive layer may or may not contain another component other than the resin component or the heat conductive filler. Examples of the other component other than the resin component or the heat conductive filler include the hot melt agent (D), the antioxidant (E), and another component described in the aforementioned section on the heat conduction layer.

When the adhesive layer contains a thermosetting resin component, from the viewpoint of improving handleability, the adhesive layer is preferably semi-cured. For example, the adhesive layer which is semi-cured is obtained by subjecting a resin composition containing a thermosetting resin component and a heat conductive filler to a treatment such as heating or drying.

In the present disclosure, “semi-cured” means that the viscosity of the adhesive layer is from 10⁴ Pa·s to 10⁶ Pa·s at room temperature (25 to 30° C.). The above viscosity is measured by DMA (dynamic viscoelasticity measuring device; frequency 1 Hz, load 10 g, temperature increase rate 20° C./min).

The method of obtaining the adhesive layer which is semi-cured is not particularly limited. For example, a resin composition containing a thermosetting resin component, a heat conductive filler, a solvent, or the like may be applied to a main surface of the heat conduction layer, and the applied resin composition may be heated, dried, or the like. Alternatively, a resin composition may be applied to a release film, then heated, dried, or the like, and then an adhesive layer made of the heated, dried, or the like resin composition may be heat roll laminated on a main surface of the heat conduction layer. Examples of methods for heating, drying, or the like include hot vacuum press, hot roll lamination, and the like.

The average thickness of the adhesive layer is preferably from 2 μm to 50 μm, more preferably from 2 μm to 30 μm, and still more preferably from 2 μm to 20 μm. When the average thickness of the adhesive layer is 2 μm or more, a gap between the adherend and the heat conduction sheet tends to be further reduced and the contact thermal resistance can be further reduced. When the average thickness of the adhesive layer is 50 μm or less, the heat conduction sheet tends to have better thermal conductivity.

The thickness may be randomly measured at three locations by observing a cross section of the heat conduction layer to be measured using an electron microscope, and the arithmetic mean value may be used as the average thickness of the adhesive layer. Alternatively, for each of the heat conduction layer not including the adhesive layer and the heat conduction sheet including the adhesive layer, the thickness is randomly measured at three locations using a micrometer, and the arithmetic mean value is calculated as each of the average thickness of the heat conduction layer and the average thickness of the heat conduction sheet. Then, the average thickness of the adhesive layer may be determined by subtracting the average thickness of the heat conduction sheet from the average thickness of the heat conduction layer.

When adhesive layers are formed on two main surfaces of the heat conduction layer, the average thickness of the adhesive layer means the total thickness of the adhesive layers formed on the two main surfaces.

The surface roughness Ra of the heat conduction sheet (before adhering to an adherend) may be 10 μm or less from the viewpoint of further reducing the gap between the adherend and the heat conduction sheet when adhering to the adherend, or may be from 2 μm to 20 μm from the viewpoint of productivity of the heat conduction sheet.

In the present disclosure, the surface roughness Ra refers to a value measured based on JIS B0601:2013.

In the heat conduction sheet, the thermal conductivity in the thickness direction of the heat conduction layer is preferably higher than the thermal conductivity in the thickness direction of the adhesive layer. For example, the ratio of the thermal conductivity in the thickness direction of the heat conduction layer with respect to the thermal conductivity in the thickness direction of the adhesive layer (thermal conductivity of the heat conduction layer/thermal conductivity of the adhesive layer) needs to be larger than 1, for example, may be greater than 1 and less than or equal to 20, may be greater than 1 and less than or equal to 10, or may be from 2 to 8.

The thermal conductivity in the thickness direction of the heat conduction layer and the thermal conductivity of the adhesive layer can be measured by a xenon flash (Xe-flash) method. Note that when the resin component includes a curable resin component, the thermal conductivity of the adhesive layer means the thermal conductivity of the adhesive layer after curing.

The thermal conductivity of the adhesive layer may be 5.0 W/(m K) or more, may be from 5.0 W/(m K) to 20 W/(m K), or may be from 7.0 W/(m K) to 15 W/(m·K).

The heat conduction sheet may have a protective film on at least one side, and preferably has a protective film on both sides. This can protect the adhesive side of the heat conduction sheet.

As the protective film, for example, resin films such as polyethylene, polyester, polypropylene, polyethylene terephthalate, polyimide, polyether imide, polyether naphthalate, methyl pentene, and the like, coated paper, coated cloth, and metal foils such as aluminum are used. These protective films may be used alone or in combination of two or more as a multilayer film. The protective film is preferably surface-treated with a silicone-based or silica-based release agent.

The use of the heat conduction sheet is not particularly limited. When the semiconductor chip is the heat generating body and the heat spreader is the heat dissipating body, the heat conduction sheet of the present disclosure is particularly suitable as a heat conduction sheet (TIM1; Thermal Interface Material 1) that interposes a semiconductor chip and a heat spreader, or as a film-like adhesive material for a semiconductor chip such as a die bonding film. When the heat conduction sheet is used as a die bonding film, it may be a dicing/die bonding integrated film layered with a dicing tape.

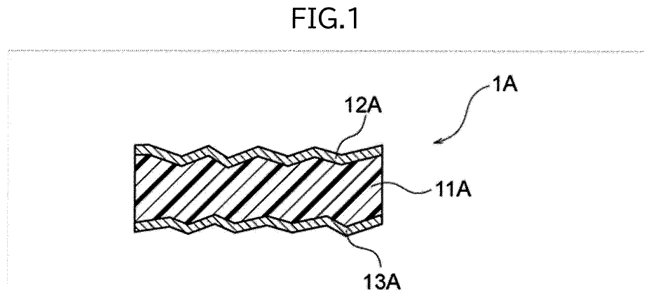

An embodiment of the heat conduction sheet will be described using FIG. 1. The heat conduction sheet of the present disclosure is not limited to the following embodiments.

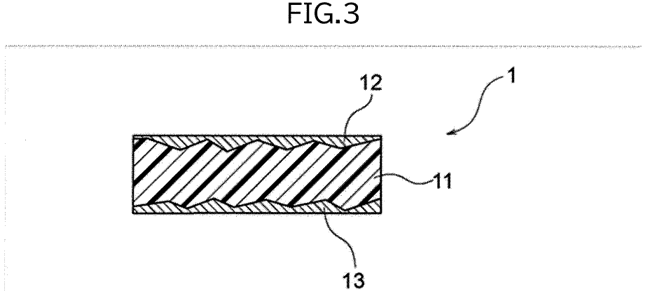

The heat conduction sheet 1A shown in FIG. 3 includes a heat conduction layer 11A and adhesive layers 12A and 13A, with the adhesive layer 12A located on one main surface of the heat conduction layer 11A, and the adhesive layer 13A located on the other main surface of the heat conduction layer 11A.

As shown in FIG. 1, the heat conduction layer 11A in the heat conduction sheet 1A does not need to be flat because its two main surfaces have an uneven shape. Alternatively, the two main surfaces of the heat conduction layer 11A in the heat conduction sheet 1A may be flat (for example, see FIG. 3).

### [Method of Manufacturing Heat Conduction Sheet]

A method of manufacturing a heat conduction sheet is not particularly limited as long as it can obtain a heat conduction sheet having the above configuration. The method of manufacturing a heat conduction sheet includes a step of preparing a composition containing the graphite particles (A) (also referred to as a “preparation step”), and a step of forming the heat conduction layer using the composition (also referred to as a “formation step”) and a step of forming an adhesive layer on at least a part of a main surface of the heat conduction layer (also referred to as an “adhesive layer forming step”).

### <Preparation Step>

In the preparation step, a composition containing graphite particles (A) and optional other components (for example, component (B) that is liquid at 25° C., acrylic acid ester polymer (C), hot melt agent (D), antioxidant (E), or other ingredients) is prepared. The method of blending each component is not particularly limited, and any method may be used as long as each component can be mixed uniformly. Alternatively, the composition may be prepared by obtaining a commercially available composition. For details on the preparation of the composition, reference can be made to paragraph of JP-A No. 2008-280496.

### <Formation Step>

In the formation step, the heat conduction layer is formed using a composition containing graphite particles (A) and optional other components. For example, the heat conduction layer may be formed by forming the aforementioned composition into a sheet shape.

It is preferable that the formation step preferably has a step (also referred to as “sheet forming step”) of forming the composition into a sheet, a step (also referred to as “layered body producing step”) of producing a layered body of the sheets, and a step (also referred to as “slicing step”) of slicing a side end face of the layered body.

### <<Sheet Forming Step>>

The sheet forming step may be performed by any method as long as the composition obtained in the previous step can be formed into a sheet, and is not particularly limited. For example, it is preferable to carry out using at least one forming method selected from the group consisting of rolling, pressing, extrusion, and coating. For details of the sheet forming step, reference can be made to paragraph of JP-A No. 2008-280496.

### <<Layered Body Producing Step>>

The layered body producing step is a step to forming a layered body of sheets obtained in the previous step. The layered body may be a form in which a plurality of independent sheets are sequentially stacked, may be a form in which one sheet is folded or may be a form in which one sheet is rolled. For details of the layered body producing step, reference can be made to paragraphs [0035] to of JP-A No. 2008-280496.

### <<Slicing Step>>

The slicing step, when the side end face of the layered body obtained in the previous step can be sliced, may be any method, and is not particularly limited. From the viewpoint that a very efficient heat conduction path is formed by the graphite particles (A) penetrating in the thickness direction of the heat conduction sheet and the thermal conductivity is further improved, it is preferable to slice by the thickness of 2 times or less of the mass average particle size of the graphite particles (A). For details of the slicing step, reference can be made to paragraph of JP-A No. 2008-280496.

### <Adhesion Layer Forming Step>

The adhesive layer forming step is not particularly limited and may be any method as long as it can form an adhesive layer on at least a portion of the main surface of the heat conduction layer (for example, a sliced sheet obtained by slicing). For example, a resin composition containing a thermosetting resin component, a heat conductive filler, a solvent, or the like is applied to a main surface of the heat conduction layer, and the applied resin composition is heated, dried, or the like to volatilize the solvent. Alternatively, the resin composition may be applied to a release film, then heated, dried, or the like, and then an adhesive layer made of the resin composition which is heated, dried, or the like, may be heat roll laminated on a main surface of the heat conduction layer. Examples of methods for heating, drying, or the like include hot vacuum pressing, hot roll lamination, and the like. The adhesive layer formed on a main surface of the heat conduction layer may be semi-cured.

The method of manufacturing a heat conduction sheet may further include a step of attaching a protective film to the heat conduction sheet and laminating it after the adhesive layer forming step (also referred to as a “lamination step”).

### <Lamination Step>

The lamination step is not particularly limited and may be any method as long as the heat conduction sheet obtained in the adhesive layer forming step can be attached to the protective film.

By manufacturing a heat conduction sheet by such a method, an efficient heat conduction path is easily formed, and therefore a heat conduction sheet with excellent high thermal conductivity and adhesion tends to be obtained.

### [Heat Dissipating Device]

A heat dissipating device of the present disclosure is a device including includes a heat generating body, a heat dissipating body, and the heat conduction sheet of the present disclosure interposed between the heat generating body and the heat dissipating body, and in the heat conduction layer, the adhesive layer is located on at least a part of a main surface located on the heat generating body side or a main surface located on the heat dissipating body side. In the heat conduction layer, it is preferable that one adhesive layer is located on at least a part of a main surface located on the heat generating body side and the other adhesive layer is located on at least a part of a main surface located on the heat dissipating body side, and it is more preferable that one adhesive layer is located on a region facing the heat generating body in a main surface located on the heat generating body side and the other adhesive layer is located on a region facing the heat dissipating body in a main surface located on the heat dissipating body side.

Examples of the heat generating body include a semiconductor chip, a semiconductor package, a power module, and the like. Examples of the heat dissipating body include a heat spreader, a heat sink, a water cooling pipe, and the like.

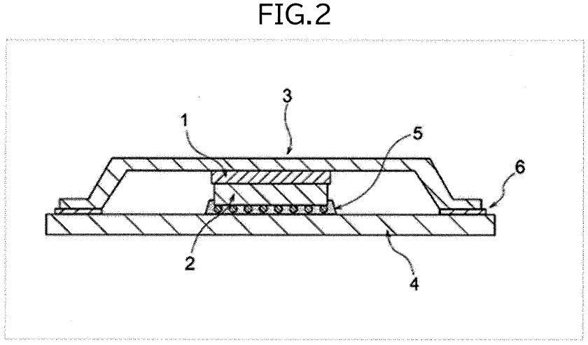

Hereinafter, an example of the heat dissipating device will be described in more detail using FIG. 2. A heat dissipating device using a semiconductor chip as a heat generating body and a heat spreader as a heat dissipating body will be described. A semiconductor chip and a heat spreader are examples of a heat generating body and a heat dissipating body, respectively, and the present disclosure is not limited thereto. The heat conduction sheet 1 is used with one side in close contact with the semiconductor chip 2 and the other side in close contact with the heat spreader 3. The semiconductor chip 2 is fixed to the substrate 4 using an underfill material 5, and the heat spreader 3 is fixed to the substrate 4 by a sealing material 6, and the adhesion between the heat conduction sheet 1, the semiconductor chip 2, and the heat spreader 3 is improved by pressing. Note that it is not necessary that one heat conduction sheet 1 has one heat generating body and one heat dissipating body. For example, a plurality of semiconductor chips 2 may be provided for one heat conduction sheet 1, one semiconductor chip 2 may be provided for a plurality of heat conduction sheets 1, and a plurality of semiconductor chips 2 may be provided for a plurality of heat conduction sheets 1. The adhesive layer is located on a main surface of the heat conduction sheet 1 on the semiconductor chip 2 side and on the other main surface of the heat conduction sheet 1 on the heat spreader 3 side. For example, in the heat conduction sheet 1 shown in FIG. 3, the adhesive layer 13 is located on a main surface of the heat conduction sheet 1 on the semiconductor chip 2 side, and the adhesive layer 12 is located on the other main surface of the heat conduction sheet 1 on the heat spreader 3 side. Furthermore, the adhesive layer 13 may be in contact with the semiconductor chip 2, and the adhesive layer 12 may be in contact with the heat spreader 3.

The heat dissipating device includes the heat conduction sheet of the present disclosure disposed between a heat generating body and a heat dissipating body. Since the heat generating body and the heat dissipating body are layered via the heat conduction sheet, heat from the heat generating body can be efficiently conducted to the heat dissipating body. Efficient heat conduction is possible, thereby the lifespan of the heat dissipating device is improved, and the heat dissipating device that functions stably even during long-term use can be provided.

The temperature range which can particularly suitably use the heat conduction sheet may be, for example, −10° C. to 150° C., may be −10° C. to 100° C., or may be −10° C. to 80° C. For this reason, suitable examples of the heat generating body include semiconductor packages, displays, LEDs, electric lights, automotive power modules, and industrial power modules.

Examples of the heat dissipating body include a heat sink using aluminum or copper fins or plates, an aluminum or copper block connected to a heat pipe, an aluminum or copper block in which a cooling liquid is circulated by a pump, and a Peltier element and an aluminum or copper block equipped with the same.

The heat dissipating device is constructed by bringing each surface of the heat conduction sheet into contact with the heat generating body and the heat dissipating body. The method of bringing the heat generating body into contact with one side of the heat conduction sheet and the method of bringing the heat dissipating body into contact with the other side of the heat conduction sheet is not particularly limited as long as they can be fixed in a sufficiently close state.

For example, the method that the heat conduction sheet is disposed between the heat generating body and the heat dissipating body, and fixed with a jig that can pressurize to about 0.05 MPa to 1 MPa, and the heat generating body is heated in this state, or they are heated to about 80° C. to 200° C. in an oven or the like, can be mentioned. Another method that a press machine capable of heating and pressing at 80° C. to 200° C. and 0.05 MPa to 1 MPa, can be mentioned. The preferred pressure range for this method is 0.10 MPa to 1 MPa, and the preferred temperature range is 100° C. to 180° C. Excellent adhesion tends to be obtained by setting the pressure to 0.10 MPa or higher or the heating temperature to 100° C. or higher. Furthermore, when the pressure is 1 MPa or less or the heating temperature is 180° C. or less, the reliability of adhesion tends to be further improved. These reason is considered to be that it is possible to prevent the heat conduction sheet from being excessively compressed and becoming thinner, and from causing excessive distortion or residual stress in a surrounding member.

The heat conduction sheet disposed between the heat generating body and the heat dissipating body is not particularly limited as long as it is the above-mentioned heat conduction sheet. For example, the heat conduction sheet shown in FIG. 1 may be disposed between the heat generating body and the heat dissipating body.

When using the heat conduction sheet 1A shown in FIG. 1, by heating and pressurizing the heat conduction sheet 1A disposed between the heat generating body and the heat dissipating body, the adhesive layers 12A and 13A located on the main surfaces of the heat conduction sheet 1A are becomes soft or deformed. A gap generated when the heat conduction sheet 1A and the heat generating body and the heat dissipating body are heat-compression bonded, is filled with the adhesive layer which is softened, deformed, or the like. Thereby, the heat conduction sheet and the adherend can be brought into close contact with each other via the adhesive layer while reducing the gap between the heat conduction sheet and the adherend. Even when a heat conduction sheet 1A whose surface is not flat as shown in FIG. 1 is used, the heat conduction sheet 1A is heated and pressurized with the heat conduction sheet 1A disposed between the heat generating body and the heat dissipating body. As a result, the heat conduction sheet 1A, which is not flat, is flattened by pressure, and when the heat dissipating device is manufactured, the heat conduction sheet 1A is flat as shown in FIG. 3, so that the occurrence of a gap between the heat conduction sheet and the adherend is suppressed.

For example, by applying an adhesive layer containing a thermosetting resin component, the adhesive layer deformed by heat compression fills a gap between the heat conduction sheet and the adherend, and the thermosetting resin component hardens by heating. Thereby, the heat conduction sheet and the adherend can be brought into close contact with each other via the adhesive layer.

For example, by applying an adhesive layer containing a thermoplastic resin component, the adhesive layer softened by heat compression fills a gap between the heat conduction sheet and the adherend.

As described above, a gap between the heat conduction sheet and the heat generating body or the heat dissipating body is reduced, and the contact thermal resistance is significantly reduced.

The heat conduction sheet may have a ratio (compression ratio) of the reduced thickness after compression with respect to its initial thickness before being disposed between the heat generating body and the heat dissipating body and being compressed, of from 1% to 35%.

In addition to a clip, a jig such as a screw or a spring may be used for fixing, and it is preferable to further fix with commonly used means such as an adhesive in order to maintain close contact.

At the interface between the heat generating body and the heat conduction sheet and at the interface between the heat dissipating body and the heat conduction sheet, the void ratio calculated as the ratio of the area of the gas region with respect to the area of the measurement region is preferably from 0% to 25.0%, and more preferably from 0% to 20.0%. Thereby, a gap generated when the heat conduction sheet and the heat generating body or heat dissipating body are heat-compression bonded (for example, a gap resulting from unevenness of the heat conduction sheet and a gap resulting from unevenness of the heat generating body or heat dissipating body) is reduced. As a result, it is assumed that the contact thermal resistance is significantly reduced.

In the present disclosure, it is preferable that the void ratio satisfies the aforementioned numerical range in both the main surface side of the heat conduction layer where the adhesive layer is located and the main surface side of the heat conduction layer where the adhesive layer is not located.

On the main surface side of the heat conduction layer where the adhesive layer is located, the aforementioned void ratio is preferably from 0% to 10.0%, more preferably from 0% to 5.0%, and still more preferably from 0% to 2.0%.

In the present disclosure, the void ratio at the interface can be determined as follows. First, using an ultrasonic image diagnostic device (for example, Insight-300, manufactured by Insight Co., Ltd.), the adhesion state at the interface is observed under the condition of a reflection method and 35 MHz. The ratio of the area of the non-adhered gas region may be calculated, and the void ratio (%) at the interface may be calculated based on the following formula.

Void ratio (%) at interface=100×(area of gas region/area of measurement region)

The numerical range of the void ratio at the interface can be adjusted by adjusting, for example, the thickness of the adhesive layer, the composition of the resin composition for forming the adhesive layer, a compression ratio of the heat conduction sheet, or the like.

### EXAMPLES

Hereinafter, the present invention will be described in more detail with reference to Examples, but the present invention is not limited to these Examples.

### Example 1 to Example 2

The following materials were put into a kneader (Moriyama Co., Ltd., DS3-SGHM-E type pressurized double-arm kneader) so that the mixing ratio (volume %) was as shown in Table 1, and kneaded at a temperature of 150° C., a composition was obtained.

### <Graphite Particles (A)>

(A)-1: Scale-like expanded graphite particles (manufactured by Showa Denko Materials co., Ltd. “HGF-L”, mass average particle size: 270 μm, by a method using X-ray diffraction measurement described above, it was confirmed that the six-membered ring face in the crystal is oriented in the plane direction of the scale-like particles.)

### <Liquid Component (B)>

(B)-1: Isobutene/Normal Butene Copolymer (NOF Corporation “NOF Polybutene Copolymer™. Emawet (registered trademark), grade 30N”)
(B)-2: Isobutene homopolymer (Nippon Oil Co., Ltd. “Tetrax 6T”)

### <Acrylic Acid Ester Polymer (C)>

(C)-1: Acrylic ester copolymer resin (butyl acrylate/ethyl acrylate/acrylonitrile/acrylic acid copolymer, weight average molecular weight: 530,000, Tg=−39° C.)

### <Hot Melt Agent (D)>

(D)-1: Hydrogenated petroleum resin (Arakawa Chemical Co., Ltd. “Alcon P90”)

### <Antioxidant (E)>

(E)-1: Hindered phenolic antioxidant (ADEKA Co., Ltd. “ADEKA STAB AO-60”)

### (Preparation of Heat Conduction Layer)

A composition obtained by kneading was put into an extrusion molding machine (Parker Co., Ltd., product name: HKS40-15 type extruder) and extruded into a flat plate shape with a width of 20 cm and a thickness of 1.5 mm to 1.6 mm to obtain a primary sheet. The obtained primary sheet was press punched using a 40 mm×150 mm die blade, and 61 of the punched sheets were layered and a spacer with a height of 80 mm was sandwiched so that the height of the sheet was 80 mm, and the pressure was applied for 30 minutes at 90° C. in the layering direction to obtain a layered body with 40 mm×150 mm×80 mm. Next, the side end face with 80 mm×150 mm of this layered body was sliced with a wood slicer to obtain a heat conduction layer with a thickness of 0.11 mm.

### (Preparation of Heat Conduction Sheet)

### Example 1

A resin composition containing 6 parts by mass of a thermosetting resin component (bisphenol F type epoxy resin), 4 parts by mass of (cresol novolac type epoxy resin), 8 parts by mass of (phenol resin), 6 parts by mass of (acrylic acid ester resin), 76 parts by mass of heat conductive filler (silver particles, particle size 1.5 μm) and 39 parts by mass of a solvent (cyclohexanone) was prepared. The prepared resin composition was applied onto a release film, and the resin composition was dried in an oven at 130° C. A heat conduction sheet with an adhesive layer (adhesive layer 1 in Table 2) formed on one main surface was obtained by hot roll laminating at 70° C. on one main surface of the heat conduction layer obtained as described above.

### Example 2

A resin composition containing 4 parts by mass of a thermosetting resin component (bisphenol F type epoxy resin), 3 parts by mass of (cresol novolac type epoxy resin), 6 parts by mass of (phenol resin), 5 parts by mass of (acrylic acid ester resin), 83 parts by mass of a heat conductive filler (silver particles, particle size 1.5 μm) and 39 parts by mass of a solvent (cyclohexanone) was prepared. The prepared resin composition was applied onto a release film, and the resin composition was dried in an oven at 130° C. A heat conduction sheet with an adhesive layer (adhesive layer 2 in Table 2) formed on one main surface was obtained by hot roll laminating at 70° C. on one main surface of the heat conduction layer obtained as described above.

### Comparative Example 1

Each material shown in Table 1 was kneaded, layered, pressed, and sliced in the same steps as in Examples 1 and 2 to produce a heat conduction layer so that the mixture ratio (volume %) was as shown in Table 1. In each comparative example, the heat conduction layer without forming an adhesive layer was used as a heat conduction sheet.

TABLE 1

| | | Volume % |
|---|---|---|
| Graphite particles (A) | (A)-1 | 33.8 |
| Liquid component (B) | (B)-1 | 28.4 |
| | (B)-2 | 13.1 |
| Acrylic acid ester polymer (C) | (C)-1 | 10.0 |
| Hot melt agent (D) | (D)-1 | 14.3 |
| Antioxidant (E) | (E)-1 | 0.4 |

| | |
|---|---|
| Total volume % | 100 |

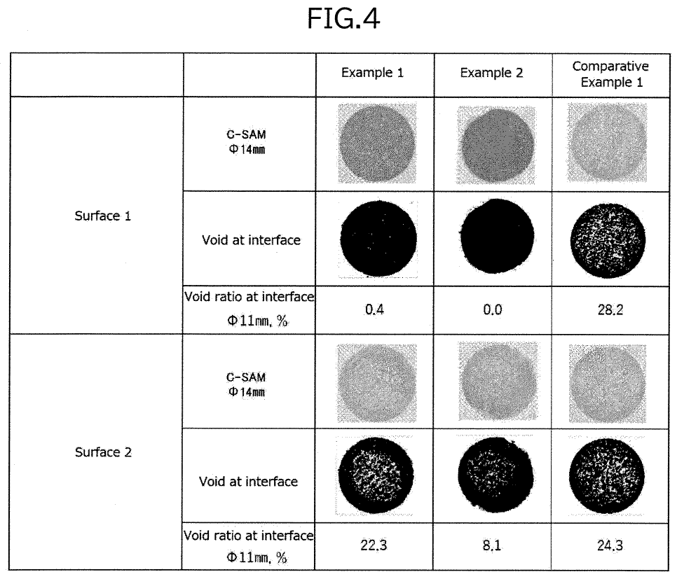

For the heat conduction sheets of Examples 1 and 2 and Comparative Example 1, each evaluation was performed by the following method. The results are shown in Table 2 and FIG. 4.

### (Measurement of Thermal Resistance)

Thermal resistance was measured using a tabletop xenon flash analyzer (LFA 467 Hyper Flash). A sample with a three-layer structure was prepared by sandwiching a heat conduction sheet with a diameter of 14 mm between 1 mm copper plates. The sample preparation conditions were a temperature of 150° C. and a pressure of 0.14 MPa, the sample was pressured for 3 minutes. When a thermosetting resin was included, in order to harden the resin, it was heated in an oven at 175° C. for 1 hour, and then sufficiently cooled at room temperature. In addition, as a pretreatment for measurement, the copper surface was blackened using carbon spray, and then measured. From the three-layer structure, the thermal conductivity 2 excluding the influence of the copper plates is obtained, and from the obtained thermal conductivity 2 and the thickness t, the unit area (1 cm²) per thermal resistance value X (K·cm²/W) was calculated as follows.

$$X = ( 10 \times t ) / λ$$

t: Thickness (mm) of heat conduction sheet of Examples 1 to 4 or Comparative Example 1
λ: Thermal conductivity (W/(m·K))

### (Evaluation of Void Ratio at Interface)

In the three-layer structure sample prepared by the method described in (Measurement of thermal resistance), the void ratio at the interface was evaluated as follows. Using an ultrasonic image diagnostic device (Insight-300, Insight Co., Ltd.), the adhesion state at the interface was observed under the condition of a reflection method, 35 MHz, gain level of 10 dB, and contrast threshold of 30% to 70%. Furthermore, the image is binarized using image analysis software (ImageJ) (specifically, 0 to 83 of the histogram are black and 84 to 255 are white), the ratio of the area of the non-adhered gas region with respect to the area of Φ11 mm (area of the measurement region; FIG. 4 shows an image of Φ14 mm) was calculated, and the void ratio (%) at the interface was calculated based on the following formula.

$$Void ratio ( \% ) at interface = 100 \times ( area of gas region / area of measurement region )$$

### (Evaluation of Thickness)

In Examples 1 and 2, the thickness of the adhesive layer before hot roll lamination was measured using a micrometer. Next, the heat conduction sheet of each of Examples 1 and 2 and Comparative Example 1 was compressed under the same conditions. Then, the maximum thickness of the heat conduction sheet after compression (“thickness after compression” in Table 2) was measured using a micrometer.

TABLE 2

| | | | | Comparative |
|---|---|---|---|---|
| | | Example 1 | Example 2 | Example 1 |
| Adhesive layer | — | 1 | 2 | — |
| Thickness of | μm | 25 | 20 | — |
| adhesive layer | | | | |
| Thermal | W/m · k | 6.7 | 10 | — |
| conductivity | | | | |
| Surface to be | — | One surface | One surface | none |
| applied | | | | |
| Thickness after | mm | 0.125 | 0.114 | 0.103 |
| compression | | | | |
| Thermal | K · cm²/W | 0.161 | 0.132 | 0.164 |
| resistance | | | | |
| Change ratio | % | −2% | −20% | — |
| of thermal | | | | |
| resistance | | | | |
| (to Comparative | | | | |
| Example 1) | | | | |
| Void ratio at | % | 0.4 | 0 | 28.2 |
| interface | | | | |
| (Surface | | | | |
| 1:surface with | | | | |
| adhesive layer) | | | | |
| Void ratio at | % | 22.3 | 8.1 | 21.3 |
| interface | | | | |
| (Surface | | | | |
| 2:surface without | | | | |
| adhesive layer) | | | | |
| thermal | — | 6.5 | 4.3 | — |
| conductivity of | | | | |
| heat conduction | | | | |
| layer/thermal | | | | |
| conductivity of | | | | |
| adhesive layer | | | | |

It was confirmed that the thermal resistance could be reduced in Examples 1 and 2, in which the adhesive layer was formed on the main surface of the heat conduction layer using the resin composition containing the resin component and the heat conductive filler, compared to Comparative Example 1, in which an adhesive layer was not formed on a main surface of the heat conduction layer.

### (Preparation of Heat Conduction Layer 1)

A heat conduction layer 1 was produced by kneading, layering, pressing, and slicing in the same steps as in Examples 1 and 2 so that each of materials shown in Table 1 had the mixing ratio (volume %) shown in Table 1.

### (Preparation of Heat Conduction Layer 2)

A heat conduction layer 2 was produced in the same as the heat conduction layer 1 except that the blending ratio of the graphite particles (A) was increased to 40.0% by volume to the blending ratio in Table 1, and the blending ratio of other components was changed as shown in Table 3.

TABLE 3

| | | Volume % |
|---|---|---|
| Graphite particles (A) | (A)-1 | 40.0 |
| Liquid component (B) | (B)-1 | 25.7 |
| | (B)-2 | 11.9 |
| Acrylic acid ester polymer (C) | (C)-1 | 9.1 |
| Hot melt agent (D) | (D)-1 | 13.0 |
| Antioxidant (E) | (E)-1 | 0.3 |

| | |
|---|---|
| Total volume % | 100 |

### (Preparation of Heat Conduction Sheet)

### Example 3

A resin composition containing 16 parts by mass of a bisphenol A type epoxy resin shown below, 1 parts by mass of bisphenol S, 83 parts by mass of heat conductive filler (silver particles, particle size 1.5 μm), 0.1 part by mass of triphenylphosphine, and 32 parts by mass of a solvent (methyl ethyl ketone) was prepared. The prepared resin composition was applied onto a release film, and heated at 70° C. for 5 minutes, and then heated at 160° C. for 2 hours to obtain a thermoplastic epoxy resin by reacting the bisphenol A type epoxy resin with bisphenol S. A heat conduction sheet with an adhesive layer (adhesive layer 3 in Table 4) formed on one main surface was obtained by hot roll laminating at 140° C. on one main surface of the heat conduction layer 1 obtained as described above.

The thickness of the adhesive layer before hot roll lamination, which was measured using a micrometer, was 10 μm.

The pressure was set at 0.14 MPa when a three-layer structure sample for thermal resistance measurement, which will be described later, was prepared.

### Example 4

A heat conduction sheet in which an adhesive layer (adhesive layer 3 in Table 4) was formed on one main surface was obtained in the same manner as in Example 3.

The thermal resistance was measured in the same manner as in Example 3, except that the pressure condition when producing a three-layer structure sample for thermal resistance measurement was changed to 0.28 MPa.

### Example 5

A heat conduction sheet in which each adhesive layer (adhesive layer 3 in Table 4) was formed on two main surface was obtained in the same manner as in Example 3, except that the two main surfaces of the heat conduction layer 1 obtained as described above were laminated with a hot roll.

The pressure was set at 0.14 MPa when a three-layer structure sample for thermal resistance measurement, which will be described later, was prepared.

### Example 6

A heat conduction sheet in which each adhesive layer (adhesive layer 3 in Table 4) was formed on two main surface was obtained in the same manner as in Example 5.

The thermal resistance was measured in the same manner as in Example 5, except that the pressure condition when producing a three-layer structure sample for thermal resistance measurement was changed to 0.28 MPa.

### Example 7

A heat conduction sheet in which each adhesive layer (adhesive layer 3 in Table 4) was formed on two main surface was obtained in the same manner as in Example 6, except that the heat conduction layer 1 was changed to the heat conduction layer 2.

The pressure was set at 0.28 MPa when a three-layer structure sample for thermal resistance measurement, which will be described later, was prepared.

### Comparative Examples 2 and 3

In Comparative Examples 2 and 3, the heat conduction layer 1 without forming an adhesive layer was used as a heat conduction sheet.

Each of the pressures was set at 0.14 MPa and 0.28 MPa when a three-layer structure sample for thermal resistance measurement, which will be described later, was prepared.

### Comparative Example 4

In Comparative Examples 2 and 3, the heat conduction layer 2 without forming an adhesive layer was used as a heat conduction sheet.

The pressure was set at 0.28 MPa when a three-layer structure sample for thermal resistance measurement, which will be described later, was prepared.

For each of the heat conduction sheets of Examples 3 to 7 and Comparative Examples 2 to 4, the thickness of the heat conduction sheet after compression was determined in the same manner as described above, and the thermal resistance of the heat conduction sheet was determined as follows. The results are shown in Table 4.

### (Measurement of Thermal Resistance)

Thermal resistance was measured using a tabletop xenon flash analyzer (LFA 467 Hyper Flash). A sample with a three-layer structure was prepared by sandwiching a heat conduction sheet with a 15 mm square between 1 mm copper plates. The sample preparation conditions were a temperature of 150° C. and a pressure of 0.14 MPa or 0.28 MPa, the sample was pressured. In order to sufficiently adhere the resin to the copper plates, it was heated in an oven at 150° C. for 30 minutes, then heated in the oven at 180° C. for 1 hour, and then sufficiently cooled at room temperature. In addition, as a pretreatment for measurement, the copper surface was blackened using carbon spray, and then measured. From the three-layer structure, the thermal conductivity 2 excluding the influence of the copper plates is obtained, and from the obtained thermal conductivity λ and the thickness t, the unit area (1 cm²) per thermal resistance value X (K·cm²/W) was calculated as follows.

$$X = ( 10 \times t ) / λ$$

t: Thickness (mm) of heat conduction sheet of Examples 1 to 4 or Comparative Example 1
λ: Thermal conductivity (W/(m·K))

TABLE 4

| | | | | | | | Comparative | | |
|---|---|---|---|---|---|---|---|---|---|
| | | Example | | | | | Example | | |
| | Unit | 3 | 4 | 5 | 6 | 7 | 1 | 2 | 3 |
| heat conduction | | 1 | 1 | 1 | 1 | 2 | 1 | 1 | 2 |
| layer | | | | | | | | | |
| Adhesive layer | | One | One | Two | Two | Two | — | — | — |
| | | surface | surface | Surface | Surface | Surface | | | |
| Pressure | Mpa | 0.14 | 0.28 | 0.14 | 0.28 | 0.28 | 0.14 | 0.28 | 0.28 |
| Temperature | | 150° C./30 min + 180° C./1 h | | | | | — | | |
| Thickness after | mm | 0.103 | 0.098 | 0.113 | 0.104 | 0.097 | 0.095 | 0.100 | 0.092 |
| compression | | | | | | | | | |
| Heat | K · cm²/w | 0.128 | 0.103 | 0.116 | 0.081 | 0.078 | 0.178 | 0.136 | 0.156 |
| resistance | | | | | | | | | |

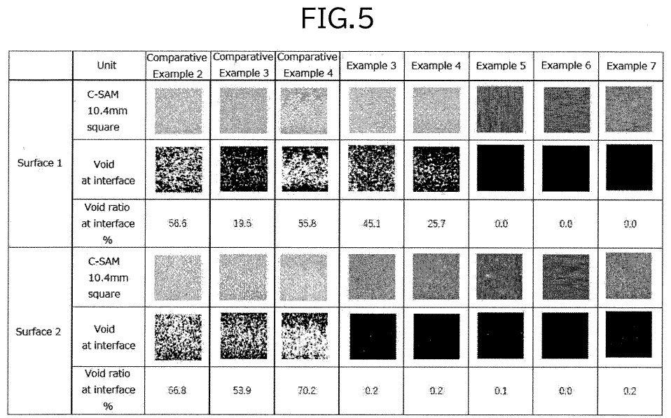

In the same manner as Examples 1 and 2, the thermal conductivity of the heat conduction layer/thermal conductivity of the adhesive layer was determined in Examples 3 to 7. Furthermore, the void ratio at the interface was determined as follows. The results are shown in Table 5 and FIG. 5.

In addition, when the adhesive layer was disposed on both sides of the heat conduction layer, the void ratio at the interface (the surface with the adhesive layer) was taken as the arithmetic mean value of the void ratio of both sides.

When the adhesive layer was not disposed on both sides of the heat conduction layer, the void ratio at the interface (the surface without the adhesive layer) was the arithmetic mean value of the void ratio of both sides.

### (Evaluation of Void Ratio at Interface)

In the three-layer structure sample prepared by the method described in (Measurement of thermal resistance), the void ratio at the interface was evaluated as follows. Using an ultrasonic image diagnostic device (Insight-350, Insight Co., Ltd.), the adhesion state at the interface was observed under the condition of a reflection method, 75 MHz, gain level of 10 dB, and contrast threshold of 30% to 70%. Furthermore, the image is binarized using image analysis software (ImageJ) (specifically, 0 to 216 of the histogram are black and 217 to 255 are white), the ratio of the area of the non-adhered gas region with respect to the area of a 10.4 mm square (area of the measurement region) was calculated, and the void ratio (%) at the interface was calculated based on the following formula.

Void ratio (%) at interface=100×(area of gas region/area of measurement region)

TABLE 5

| | | | | | | | Comparative | | |
|---|---|---|---|---|---|---|---|---|---|
| | | Example | | | | | Example | | |
| | Unit | 3 | 4 | 5 | 6 | 7 | 1 | 2 | 3 |
| heat conduction | | 1 | 1 | 1 | 1 | 2 | 1 | 1 | 2 |
| layer | | | | | | | | | |
| Adhesive layer | | One | One | Two | Two | Two | — | — | — |
| | | surface | surface | Surface | Surface | Surface | | | |
| Void ratio at | % | 0.2 | 0.2 | 0.1 | 0 | 0.1 | — | — | — |
| interface | | | | | | | | | |
| (Surface with | | | | | | | | | |
| adhesive layer) | | | | | | | | | |
| Void ratio at | % | 22/6 | 13.0 | — | — | — | 61.7 | 36.7 | 63.0 |
| interface | | | | | | | | | |
| (Surface without | | | | | | | | | |
| adhesive layer) | | | | | | | | | |
| Heat conductivity | % | 5.1 | 5.1 | 5.1 | 5.1 | 7.2 | — | — | — |
| of heat conduction | | | | | | | | | |
| layer/heat | | | | | | | | | |
| conductivity of | | | | | | | | | |
| adhesive layer | | | | | | | | | |

As shown in Table 4, it was confirmed that the thermal resistance could be reduced in Examples 3 to 7, in which the adhesive layer was formed on the main surface of the heat conduction layer using the resin composition containing the thermoplastic resin component and the heat conductive filler, compared to Comparative Examples 2 to 4, in which an adhesive layer was not formed on a main surface of the heat conduction layer.

As shown in Table 5, it was assumed that the values of the void ratio in Examples 3 to 7 were lower than those in Comparative Examples 2 to 4 and the thermal resistance could be reduced by lowering the void ratio at the interface.

All publications, patent applications, and technical standards mentioned in the present specification are herein incorporated by reference to the same extent as if each individual publication, patent application, and technical standard were specifically and individually indicated to be incorporated by reference.

1. A heat conduction sheet, comprising:
a heat conduction layer containing at least one kind of graphite particles (A) selected from the group consisting of scale-like particles, ellipsoidal particles and rod-like particles, wherein in a case of scale-like particles, a plane direction of the particle is oriented in a thickness direction of the heat conduction sheet, and in a case of ellipsoidal particles or rod-like particles, a long axis direction of the particle is oriented in the thickness direction of the heat conduction sheet, and
an adhesive layer containing a resin component and a heat conductive filler, which is located on at least a part of a main surface of the heat conduction layer.

2. The heat conduction sheet according to claim 1, wherein the resin component contains at least one selected from the group consisting of a curable resin component, an adhesive resin component, and a thermoplastic resin component.

3. The heat conduction sheet according to claim 2, wherein the resin component is a curable resin component, and the adhesive layer is semi-cured.

4. The heat conduction sheet according to claim 1, wherein the resin component contains a thermoplastic resin component.

5. The heat conduction sheet according to claim 1, wherein the thermoplastic resin component contains a thermoplastic epoxy resin.

6. The heat conduction sheet according to claim 1, wherein the heat conductive filler contains at least one kind of particles selected from the group consisting of silver, copper, aluminum, aluminum oxide, aluminum hydroxide, magnesium oxide, beryllium oxide, boron nitride, aluminum nitride, silicon nitride, silicon carbide, silicon dioxide, aluminum fluoride, calcium fluoride and zinc oxide.

7. The heat conduction sheet according to claim 6, wherein the heat conductive filler contains silver particles.

8. The heat conduction sheet according to claim 1, wherein a content ratio of the heat conductive filler is from 70% by mass to 99% by mass with respect to a total amount of the adhesive layer.

9. The heat conduction sheet according to claim 1, wherein an average thickness of the adhesive layer is from 2 μm to 50 μm.

10. A heat dissipating device, comprising a heat generating body, a heat dissipating body, and the heat conduction sheet according to claim 1 interposed between the heat generating body and the heat dissipating body,
wherein in the heat conduction layer, the adhesive layer is located on at least a part of a main surface located on the heat generating body side or a main surface located on the heat dissipating body side.

11. A heat dissipating device, comprising a heat generating body, a heat dissipating body, and the heat conduction sheet according to claim 1 interposed between the heat generating body and the heat dissipating body,
wherein in at least one of an interface between the heat generating body and the heat conduction sheet or an interface between the heat dissipating body and the heat conduction sheet, a void ratio calculated as a ratio of an area of a gas region with respect to an area of a measurement region is from 0% to 25%.

12. A method of manufacturing the heat conduction sheet according to claim 1, comprising:
preparing a composition containing the graphite particles (A), forming the heat conduction layer using the composition, and forming an adhesive layer on at least a part of a main surface of the heat conduction layer.
